(19) United States
(12) Patent Application Publication
(10) Pub. No.: US 2013/0234760 A1
(43) Pub. Date: Sep. 12, 2013

(54) OUTPUT BUFFER

(71) Applicants: Jia-Hui Wang, Tainan City (TW); Hung-Yu Huang, Tainan City (TW)

(72) Inventors: Jia-Hui Wang, Tainan City (TW); Hung-Yu Huang, Tainan City (TW)

(73) Assignee: HIMAX TECHNOLOGIES LIMITED, Tainan City (TW)

(21) Appl. No.: 13/413,309

(22) Filed: Mar. 6, 2012

(51) Int. Cl. H03B 1/00

(52) U.S. Cl. 327/108

(57) ABSTRACT

An output buffer including a P-type transistor, an N-type transistor, a first comparison unit and a second comparison unit is provided. The P-type transistor has a first source, a first gate and a first drain. The first source receives a system voltage, and the first drain outputs an output voltage. The N-type transistor has a second drain, a second gate and a second source. The second drain is coupled to the first drain, and the second source receives a ground voltage. The first comparison unit and the second comparison unit respectively output a high voltage or a low voltage to the first gate and the second gate according to a comparison result of an input voltage and the output voltage, and respectively regulate a first tail current flowing into the first comparison unit and a second tail current flowing from the second comparison unit accordingly.

### BACKGROUND OF THE INVENTION

1. Field of the Invention

The present invention generally relates to an output buffer, in particular, to a rail-to-rail output buffer.

2. Description of Related Art

With the development of photoelectric and semiconductor devices, a flat-panel display such as a liquid crystal display (LCD) is developed rapidly in recent years. The LCD, advantageous in having low power consumption, no radiation and high space utilization, gradually becomes the mainstream of the market. A source driver is a rather important device in the LCD, which may convert a digital data signal of a display image into an analog signal, and output the analog signal to each pixel on a display panel.

Generally, the source driver includes multiple data channels to transmit the analog signal to pixels on each data line, and also includes multiple output buffers to improve the signal transmission strength, so as to charge/discharge the display panel. Therefore, the output buffer greatly influences the whole source driver, and with increasing functions of portable electronic products, the output buffer inevitably develops toward the specification of low power consumption and small area.

### SUMMARY OF THE INVENTION

The present invention provides an output buffer, which is capable of regulating an output voltage in quick response to a change of an input voltage when the input voltage is different from the output voltage.

The present invention provides an output buffer, including a first P-type transistor, a first N-type transistor, a first comparison unit and a second comparison unit. The first P-type transistor has a first source, a first gate and a first drain. The first source receives a system voltage, and the first drain outputs an output voltage. The first N-type transistor has a second drain, a second gate and a second source. The second drain is coupled to the first drain, and the second source receives a ground voltage. The first comparison unit receives an input voltage and the output voltage, compares the input voltage and the output voltage, outputs a high voltage or a low voltage to the first gate according to a comparison result, and regulates a first tail current flowing into the first comparison unit accordingly. The second comparison unit receives the input voltage and the output voltage, compares the input voltage and the output voltage, outputs the high voltage or the low voltage to the second gate according to the comparison result, and regulates a second tail current flowing from the second comparison unit accordingly.

In an embodiment of the present invention, when the input voltage is greater than the output voltage, the first comparison unit outputs the low voltage to the first gate, and the second comparison unit outputs the low voltage to the second gate; while when the input voltage is smaller than the output voltage, the first comparison unit outputs the high voltage to the first gate, and the second comparison unit outputs the high voltage to the second gate.

In an embodiment of the present invention, when the input voltage is greater than the output voltage, the first comparison unit is in an OFF state to reduce the first tail current received by the first comparison unit from the system voltage, and the second comparison unit is in an ON state to increase the second tail current output by the second comparison unit to the ground voltage; while when the input voltage is smaller than the output voltage, the first comparison unit is in the ON state to increase the first tail current received by the first comparison unit from the system voltage, and the second comparison unit is in the OFF state to reduce the second tail current output by the second comparison unit to the ground voltage.

In an embodiment of the present invention, the first comparison unit includes a second P-type transistor, a P-type differential circuit and a first current source. The second P-type transistor has a third source, a third gate and a third drain. The third source receives the system voltage to receive the first tail current. The P-type differential circuit has a first input end, a second input end, a first output end, a first power terminal and a second power terminal. The first input end receives the output voltage, the second input end receives the input voltage, the first output end is coupled to the first gate, the first power terminal is coupled to the third drain, and the second power terminal is coupled to the third gate. The first current source is coupled between the second power terminal and the ground voltage.

In an embodiment of the present invention, the P-type differential circuit includes a third P-type transistor and a fourth P-type transistor. The third P-type transistor has a fourth source, a fourth gate and a fourth drain. The fourth source is coupled to the first power terminal, the fourth drain is coupled to the second power terminal, and the fourth gate is coupled to the first input end. The fourth P-type transistor has a fifth source, a fifth gate and a fifth drain. The fifth source is coupled to the first power terminal, the fifth drain is coupled to the first output end, and the fifth gate is coupled to the second input end.

In an embodiment of the present invention, the second comparison unit includes a second N-type transistor, an N-type differential circuit and a second current source. The second N-type transistor has a sixth drain, a sixth gate and a sixth source. The sixth source receives the ground voltage to output the second tail current. The N-type differential circuit has a third input end, a fourth input end, a second output end, a third power terminal and a fourth power terminal. The third input end receives the output voltage, the fourth input end receives the input voltage, the second output end is coupled to the second gate, the third power terminal is coupled to the sixth gate, and the fourth power terminal is coupled to the sixth drain. The second current source is coupled between the system voltage and the third power terminal.

In an embodiment of the present invention, the N-type differential circuit includes a third N-type transistor and a fourth N-type transistor. The third N-type transistor has a seventh drain, a seventh gate and a seventh source. The seventh drain is coupled to the third power terminal, the seventh source is coupled to the fourth power terminal, and the seventh gate is coupled to the third input end. The fourth N-type transistor has an eighth drain, an eighth gate and an eighth source. The eighth drain is coupled to the second output end, the eighth source is coupled to the fourth power terminal, and the eighth gate is coupled to the fourth input end.

In an embodiment of the present invention, the output buffer further includes a bias unit, coupled to the first gate and the second gate, and used for providing a bias.

In an embodiment of the present invention, the bias unit includes a fifth P-type transistor and a fifth N-type transistor. The fifth P-type transistor has a ninth source, a ninth gate and a ninth drain. The ninth source is coupled to the first gate, the ninth drain is coupled to the second gate, and the ninth gate receives a first reference voltage. The fifth N-type transistor has a tenth drain, a tenth gate and a tenth source. The tenth drain is coupled to the first gate, the tenth source is coupled to the second gate, and the tenth gate receives a second reference voltage.

In an embodiment of the present invention, the high voltage is the system voltage.

In an embodiment of the present invention, the low voltage is the ground voltage.

In view of the above, in the output buffer according to the embodiment of the present invention, the first comparison unit and the second comparison unit compare the input voltage and the output voltage, and control the P-type transistor and the N-type transistor to be turned on or off accordingly, and synchronously regulate the first tail current and the second tail current of the first comparison unit and the second comparison unit, thereby achieving the capability of quickly responding in a transient state to a voltage difference between the input voltage and the output voltage.

In order to make the aforementioned features and advantages of the present invention more comprehensible, embodiments are described in detail below with reference to the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic system diagram of an output buffer according to an embodiment of the present invention.

FIG. 2 is a schematic circuit diagram of an output buffer according to an embodiment of the present invention.

FIG. 3 is a schematic diagram of a driving waveform when the input voltage in FIG. 2 rises according to an embodiment of the present invention.

FIG. 4 is a schematic diagram of a driving waveform when the input voltage in FIG. 2 drops according to an embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

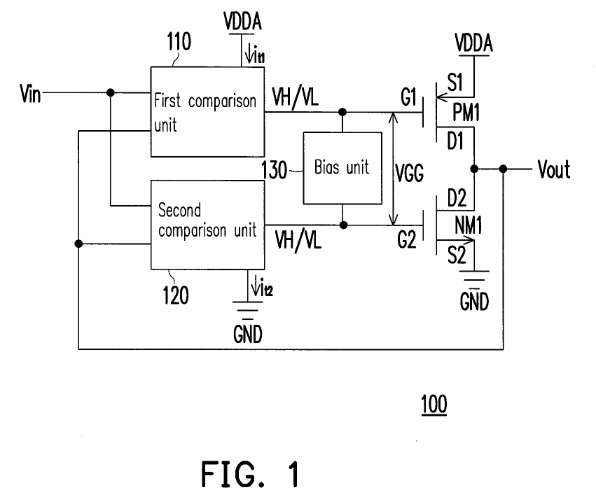

FIG. 1 is a schematic system diagram of an output buffer according to an embodiment of the present invention. Referring to FIG. 1, in this embodiment, the output buffer 100 includes a first P-type transistor PM1, a first N-type transistor NM1, a first comparison unit 110, a second comparison unit 120 and a bias unit 130. The first P-type transistor PM1 and the first N-type transistor NM1 may be regarded as output stages of the output buffer 100. The first P-type transistor PM1 has a first source S1, a first gate G1 and a first drain D1. The first source S1 receives a system voltage VDDA, and the first drain D1 outputs an output voltage Vout. The first N-type transistor NM1 has a second drain D2, a second gate G2 and a second source S2. The second drain D2 is coupled to the first drain D1, and the second source S2 receives the ground voltage GND.

The bias unit 130 is coupled to the first gate G1 and the second gate G2, and used for providing a bias VGG to the first gate G1 and the second gate G2. The first comparison unit 110 receives an input voltage Vin and the output voltage Vout, compares the input voltage Vin and the output voltage Vout, outputs a high voltage VH or a low voltage VL to the first gate G1 according to a comparison result, and regulates a first tail current iₜ₁ flowing from the system voltage VDDA into the first comparison unit 110 accordingly. The second comparison unit 120 receives the input voltage Vin and the output voltage Vout, compares the input voltage Vin and the output voltage Vout, outputs the high voltage VH or the low voltage VL to the second gate G2 according to the comparison result, and regulating a second tail current iₜ₂ flowing from the second comparison unit 120 into the ground voltage GND.

When the input voltage Vin is greater than the output voltage Vout, the first comparison unit 110 outputs the low voltage VL to the first gate G1 to turn on the first P-type transistor PM1, so that the system voltage VDDA charges an output end (an end corresponding to the output voltage Vout), and the second comparison unit outputs the low voltage VL to the second gate to turn off the first N-type transistor NM1, so as to prevent the output end from discharging through the first N-type transistor NM1. In this case, the first comparison unit 110 is in an OFF state to reduce the first tail current iₜ₁ received by the first comparison unit 110 from the system voltage VDDA, and the second comparison unit 120 is in an ON state to increase the second tail current iₜ₂ output by the second comparison unit 120 to the ground voltage GND.

When the input voltage Vin is smaller than the output voltage Vout, the first comparison unit 110 outputs the high voltage VH to the first gate G1 to turn off the first P-type transistor PM1, so as to prevent the output end from charging through the first P-type transistor PM1, and the second comparison unit 120 outputs the high voltage VH to the second gate G2 to turn on the first N-type transistor NM1, so that the ground voltage GND discharges the output end. In this case, the first comparison unit 110 is in the ON state to increase the first tail current iₜ₁ received by the first comparison unit 110 from the system voltage VDDA, and the second comparison unit is in the OFF state to reduce the second tail current iₜ₂ output by the second comparison unit 120 to the ground voltage GND.

In view of the above, when the input voltage Vin ranges from the system voltage VDDA to the ground voltage GND, the output voltage Vout also ranges from the system voltage VDDA to the ground voltage GND. Therefore, in the embodiment of the present invention, the output buffer 100 may be a rail-to-rail output buffer. Further, since the first comparison unit 110 regulates the first tail current iₜ₁ flowing from the system voltage VDDA into the first comparison unit 110 according to the comparison result between the input voltage Vin and the output voltage Vout, and the second comparison unit 120 regulates the second tail current iₜ₂ flowing from the second comparison unit 120 into the ground voltage GND according to the comparison result between the input voltage Vin and the output voltage Vout, the response of the output buffer 100 to a voltage difference between the input voltage Vin and the output voltage Vout is accelerated, that is, the duration of the transient state of the output voltage Vout is shortened.

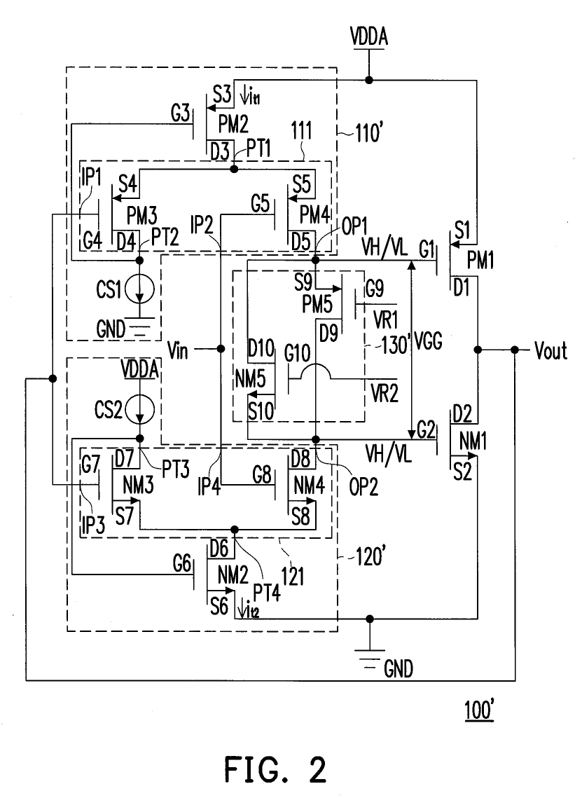

FIG. 2 is a schematic circuit diagram of an output buffer according to an embodiment of the present invention. Referring to FIG. 1 and FIG. 2, in this embodiment, the first comparison unit 110′ in the output buffer 100′ includes a second P-type transistor PM2, a P-type differential circuit 111, and a first current source CS1. The second P-type transistor PM2 has a third source S3, a third gate G3 and a third drain D3. The third source S3 receives the system voltage VDDA to receive the first tail current iₜ₁. The P-type differential circuit 111 has a first input end IP1, a second input end IP2, a first output end OP1, a first power terminal PT1 and a second power terminal PT2. The first input end IP1 receives the output voltage Vout, the second input end IP2 receives the input voltage Vin, the first output end OP1 is coupled to the first gate G1, the first power terminal PT1 is coupled to the third drain D3, and the second power terminal PT2 is coupled to the third gate G3. The first current source CS1 is coupled between the second power terminal PT2 and the ground voltage GND.

The P-type differential circuit 111 includes a third P-type transistor PM3 and a fourth P-type transistor PM4. The third P-type transistor PM3 has a fourth source S4, a fourth gate G4 and a fourth drain D4. The fourth source S4 is coupled to the first power terminal PT1, the fourth drain D4 is coupled to the second power terminal PT2, and the fourth gate G4 is coupled to the first input end IP 1. The fourth P-type transistor PM4 has a fifth source S5, a fifth gate G5 and a fifth drain D5. The fifth source S5 is coupled to the first power terminal PT1, the fifth drain D5 is coupled to the first output end OP1, and the fifth gate G5 is coupled to the second input end IP2.

In this embodiment, the second comparison unit 120′ in the output buffer 100′ includes a second N-type transistor NM2, an N-type differential circuit 121 and a second current source CS2. The second N-type transistor NM2 has a sixth drain D6, a sixth gate G6 and a sixth source S6. The sixth source S6 receives the ground voltage GND to output the second tail current iₜ₂. The N-type differential circuit 121 has a third input end IP3, a fourth input end IP4, a second output end OP2, a third power terminal PT3 and a fourth power terminal PT4. The third input end IP3 receives the output voltage Vout, the fourth input end IP4 receives the input voltage Vin, the second output end OP2 is coupled to the second gate G2, the third power terminal PT3 is coupled to the sixth gate G6, and the fourth power terminal PT4 is coupled to the sixth drain D6. The second current source CS2 is coupled between the system voltage VDDA and the third power terminal PT3.

The N-type differential circuit 121 includes a third N-type transistor NM3 and a fourth N-type transistor NM4. The third N-type transistor NM3 has a seventh drain D7, a seventh gate G7 and a seventh source S7. The seventh drain D7 is coupled to the third power terminal PT3, the seventh source S7 is coupled to the fourth power terminal PT4, and the seventh gate G7 is coupled to the third input end IP3. The fourth N-type transistor NM4 has an eighth drain D8, an eighth gate G8 and an eighth source S8. The eighth drain D8 is coupled to the second output end OP2, the eighth source S8 is coupled to the fourth power terminal PT4, and the eighth gate G8 is coupled to the fourth input end IP4.

In this embodiment, the bias unit 130′ includes a fifth P-type transistor PM5 and a fifth N-type transistor NM5. The fifth P-type transistor PM5 has a ninth source S9, a ninth gate G9 and a ninth drain D9. The ninth source S9 is coupled to the first gate G1, the ninth drain D9 is coupled to the second gate G2, and the ninth gate G9 receives a first reference voltage VR1. The fifth P-type transistor PM5 is turned on or off under the control of the first reference voltage VR1. The fifth N-type transistor NM5 has a tenth drain D10, a tenth gate G10 and a tenth source S10. The tenth drain D10 is coupled to the first gate G1, the ninth source S9 is coupled to the second gate G2, and the tenth gate G10 receives a second reference voltage VR2. The fifth N-type transistor NM5 is turned on or off under the control of the second reference voltage VR2.

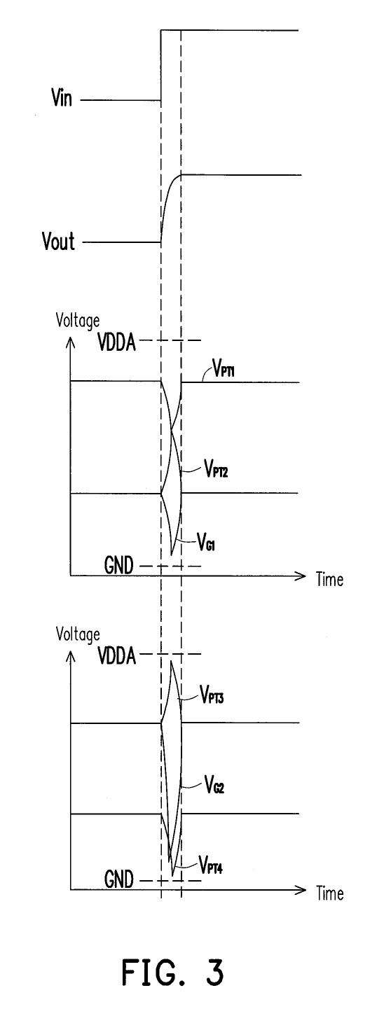

FIG. 3 is a schematic diagram of a driving waveform when the input voltage in FIG. 2 rises according to an embodiment of the present invention. Referring to FIG. 2 and FIG. 3, in this embodiment, when the input voltage Vin rises (a rising edge of the input voltage Vin is shown in FIG. 3), the input voltage Vin is greater than the output voltage Vout, indicating that the output buffer 100′ charges the output end (not shown) to raise the output voltage Vout. In this case, when the input voltage Vin rises, the channel of the fourth P-type transistor PM4 is narrowed, and the current flowing into the third P-type transistor PM3 is increased, so that the voltage V_{PT2} of the second power terminal PT2 rises. When the voltage V_{PT2} of the second power terminal PT2 rises, the channel of the second P-type transistor PM2 is narrowed, and the first tail current iₜ₁ is decreased, so that the voltage V_{PT1} of the first power terminal PT1 drops. When the voltage V_{PT1} of the first power terminal PT1 drops, the turn-off speed of the channel of the fourth P-type transistor PM4 is accelerated. Thereby, the first comparison unit 110′ is in the OFF state, and the charging capability of the first comparison unit 110′ on the first gate G1 and the second gate G2 is greatly deteriorated and even disappears (that is, no charging capability is provided).

When the input voltage Vin rises, the channel of the fourth N-type transistor NM4 is enlarged, and the current flowing from the third N-type transistor NM3 into the second N-type transistor NM2 is reduced, so that the voltage V_{PT3} of the third power terminal PT3 rises. When the voltage V_{PT3} of the third power terminal PT3 rises, the channel of the second N-type transistor NM2 is enlarged, and the second tail current iₜ₂ is increased, so that the voltage V_{PT4} of the fourth power terminal PT4 drops. When the voltage V_{PT4} of the fourth power terminal PT4 drops, the turn-on speed of the channel of the fourth N-type transistor NM4 is accelerated. Thereby, the second comparison unit 120′ is in the ON state, so that the discharging capability of the second comparison unit 120′ on the first gate G1 and the second gate G2 is greatly enhanced.

In view of the above, when the input voltage Vin rises, the first comparison unit 110′ is in the OFF state so that the charging capability thereof is deteriorated or disappears, and the second comparison unit 120′ is in the ON state so that the discharging capability thereof is enhanced. In this case, the voltage V_{G1} and V_{G2} of the first gate G1 and the second gate G2 rapidly drop to be close to or equal to the ground voltage GND, that is, the low voltage VL output by the first comparison unit 110′ and the second comparison unit 120′ is close to or equal to the ground voltage GND, so that the channel of the first P-type transistor PM1 is rapidly turned on to improve the charging capability thereof, and the channel of the first N-type transistor NM1 is rapidly turned off to deteriorate the discharging capability thereof. In the case that the channel of the first P-type transistor PM1 is rapidly turned on and the channel of the first N-type transistor NM1 is rapidly turned off, the charging speed of the output end is accelerated, that is, the rising speed of the output voltage Vout is accelerated, thereby significantly reducing the duration of the transient state of the output voltage Vout when rising.

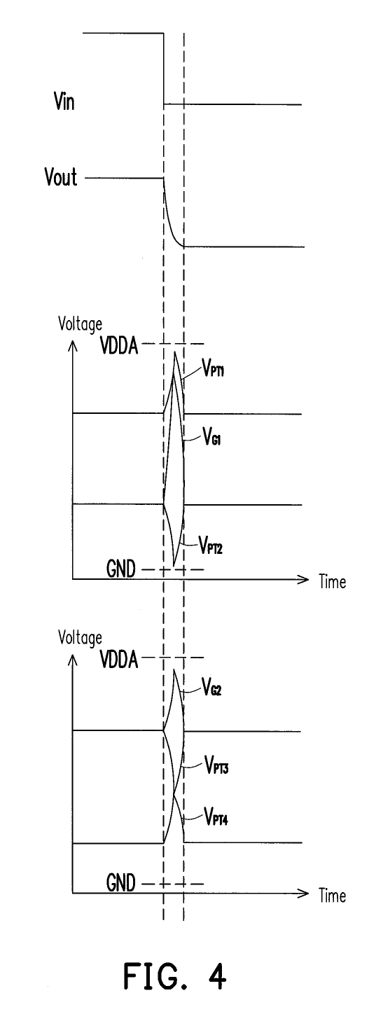

FIG. 4 is a schematic diagram of a driving waveform when the input voltage in FIG. 2 drops according to an embodiment of the present invention. Referring to FIG. 2 and FIG. 4, in this embodiment, when the input voltage Vin drops (a falling edge of the input voltage Vin is shown in FIG. 4), the input voltage Vin is smaller than the output voltage Vout, indicating that the output buffer 100′ discharges the output end (not shown) to reduce the output voltage Vout. In this case, when the input voltage Vin drops, the channel of the fourth P-type transistor PM4 is enlarged, and the current flowing into the third P-type transistor PM3 is reduced, so that the voltage V_{PT2} of the second power terminal PT2 drops. When the voltage V_{PT2} of the second power terminal PT2 drops, the channel of the second P-type transistor PM2 is enlarged, and the first tail current iₜ₁ is increased, so that the voltage V_{PT1} of the first power terminal PT1 rises. In the case that the voltage V_{PT1} of the first power terminal PT1 rises, the turn-on speed of the channel of the fourth P-type transistor PM4 is accelerated. Thereby, the first comparison unit 110′ is in the ON state, and the charging capability of the first comparison unit 110′ on the first gate G1 and the second gate G2 is greatly enhanced.

When the input voltage Vin drops, the channel of the fourth N-type transistor NM4 is narrowed, and the current flowing from the third N-type transistor NM3 into the second N-type transistor NM2 is increased, so that the voltage V_{PT3} of the third power terminal PT3 drops. When the voltage V_{PT3} of the third power terminal PT3 drops, the channel of the second N-type transistor NM2 is narrowed, and the second tail current iₜ₂ is reduced, so that the voltage V_{PT4} of the fourth power terminal PT4 rises. When the voltage V_{PT4} of the fourth power terminal PT4 rises, the turn-off speed of the channel of the fourth N-type transistor NM4 is accelerated. Thereby, the second comparison unit 120′ is in the OFF state, and the discharging capability of the second comparison unit 120′ on the first gate G1 and the second gate G2 is greatly deteriorated and even disappears (that is, no discharging capability is provided).

In view of the above, when the input voltage Vin drops, the first comparison unit 110′ is in the ON state so that the charging capability thereof is enhanced, and the second comparison unit 120′ is in the ON state so that the discharging capability thereof is deteriorated or disappears. In this case, the voltage V_{G1} and V_{G2} of the first gate G1 and the second gate G2 rapidly rise to be close to or equal to the system voltage VDDA, that is, the high voltage VH output by the first comparison unit 110′ and the second comparison unit 120′ is close to or equal to the system voltage VDDA, so that the channel of the first P-type transistor PM1 is rapidly turned off to deteriorate the charging capability thereof, and the channel of the first N-type transistor NM1 is rapidly turned on to increase the discharging capability thereof. In the case that the channel of the first P-type transistor PM1 is rapidly turned off and the channel of the first N-type transistor NM1 is rapidly turned on, the discharging speed of the output end is accelerated, that is, the dropping speed of the output voltage Vout is accelerated, thereby significantly reducing the duration of the transient state of the output voltage Vout when dropping.

As described above, in this embodiment, the output buffer 100′ may be implemented through a simple circuit, and thus can work with an extremely low quiescent current. Moreover, compared with the conventional rail-to-rail output buffer, the output buffer 100′ of this embodiment requires fewer transistors, so that the area of the chips of the source driver is largely reduced.

Therefore, in the output buffer according to the embodiment of the present invention, the first comparison unit and the second comparison unit control the P-type transistor and the N-type transistor to be turned on or off according to the comparison result between the input voltage and the output voltage, and synchronously regulate the first tail current and the second tail current of the first comparison unit and the second comparison unit, thereby achieving the capability of quickly responding in a transient state to a voltage difference between the input voltage and the output voltage. Moreover, the output buffer may be implemented through a simple circuit, and thus can work with an extremely low quiescent current. In addition, the area of the chips of the source driver is largely reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An output buffer, comprising:
a first P-type transistor, having a first source, a first gate and a first drain, wherein the first source receives a system voltage, and the first drain outputs an output voltage;
a first N-type transistor, having a second drain, a second gate and a second source, wherein the second drain is coupled to the first drain, and the second source receives a ground voltage;
a first comparison unit, for receiving an input voltage and the output voltage, comparing the input voltage and the output voltage, outputting a high voltage or a low voltage to the first gate according to a comparison result, and regulating a first tail current flowing into the first comparison unit accordingly; and
a second comparison unit, for receiving the input voltage and the output voltage, comparing the input voltage and the output voltage, outputting the high voltage or the low voltage to the second gate according to the comparison result, and regulating a second tail current flowing from the second comparison unit accordingly.

2. The output buffer according to claim 1, wherein when the input voltage is greater than the output voltage, the first comparison unit outputs the low voltage to the first gate, and the second comparison unit outputs the low voltage to the second gate; while when the input voltage is smaller than the output voltage, the first comparison unit outputs the high voltage to the first gate, and the second comparison unit outputs the high voltage to the second gate.

3. The output buffer according to claim 2, wherein when the input voltage is greater than the output voltage, the first comparison unit is in an OFF state to reduce the first tail current received by the first comparison unit from the system voltage, and the second comparison unit is in an ON state to increase the second tail current output by the second comparison unit to the ground voltage; while when the input voltage is smaller than the output voltage, the first comparison unit is in the ON state to increase the first tail current received by the first comparison unit from the system voltage, and the second comparison unit is in the OFF state to reduce the second tail current output by the second comparison unit to the ground voltage.

4. The output buffer according to claim 1, wherein the first comparison unit comprises:
a second P-type transistor, having a third source, a third gate and a third drain, wherein the third source receives the system voltage to receive the first tail current;
a P-type differential circuit, having a first input end, a second input end, a first output end, a first power terminal and a second power terminal, wherein the first input end receives the output voltage, the second input end receives the input voltage, the first output end is coupled to the first gate, the first power terminal is coupled to the third drain, and the second power terminal is coupled to the third gate; and
a first current source, coupled between the second power terminal and the ground voltage.

5. The output buffer according to claim 4, wherein the P-type differential circuit comprises:
a third P-type transistor, having a fourth source, a fourth gate and a fourth drain, wherein the fourth source is coupled to the first power terminal, the fourth drain is coupled to the second power terminal, and the fourth gate is coupled to the first input end; and
a fourth P-type transistor, having a fifth source, a fifth gate and a fifth drain, wherein the fifth source is coupled to the first power terminal, the fifth drain is coupled to the first output end, and the fifth gate is coupled to the second input end.

6. The output buffer according to claim 1, wherein the second comparison unit comprises:
a second N-type transistor, having a sixth drain, a sixth gate and a sixth source, wherein the sixth source receives the ground voltage to output the second tail current;
an N-type differential circuit, having a third input end, a fourth input end, a second output end, a third power terminal and a fourth power terminal, wherein the third input end receives the output voltage, the fourth input end receives the input voltage, the second output end is coupled to the second gate, the third power terminal is coupled to the sixth gate, and the fourth power terminal is coupled to the sixth drain; and
a second current source, coupled between the system voltage and the third power terminal.

7. The output buffer according to claim 6, wherein the N-type differential circuit comprises:
a third N-type transistor, having a seventh drain, a seventh gate and a seventh source, wherein the seventh drain is coupled to the third power terminal, the seventh source is coupled to the fourth power terminal, and the seventh gate is coupled to the third input end; and
a fourth N-type transistor, having an eighth drain, an eighth gate and an eighth source, wherein the eighth drain is coupled to the second output end, the eighth source is coupled to the fourth power terminal, and the eighth gate is coupled to the fourth input end.

8. The output buffer according to claim 1, further comprising:
a bias unit, coupled to the first gate and the second gate, and used for providing a bias.

9. The output buffer according to claim 1, wherein the bias unit comprises:
a fifth P-type transistor, having a ninth source, a ninth gate and a ninth drain, wherein the ninth source is coupled to the first gate, the ninth drain is coupled to the second gate, and the ninth gate receives a first reference voltage; and
a fifth N-type transistor, having a tenth drain, a tenth gate and a tenth source, wherein the tenth drain is coupled to the first gate, the tenth source is coupled to the second gate, and the tenth gate receives a second reference voltage.

10. The output buffer according to claim 1, wherein the high voltage is the system voltage.

11. The output buffer according to claim 1, wherein the low voltage is the ground voltage.
